(19) United States
(12) Patent Application Publication
(10) Pub. No.: US 2007/0030870 A1
(43) Pub. Date: Feb. 8, 2007

(54) Method and structure for ridge waveguide quantum cascade laser with p-type overgrowth

(76) Inventors: David P. Bour, Cupertino, CA (US); Scott W. Corzine, Sunnyvale, CA (US)

Correspondence Address: AGILENT TECHNOLOGIES INC., INTELLECTUAL PROPERTY ADMINISTRATION, M/S DU404, P.O. BOX 7599, LOVELAND, CO, 80537-0599, US

(21) Appl. No.: 11/191,773

(22) Filed: Jul. 27, 2005

(51) Int. Cl. H01S 5/00

(52) U.S. Cl. 372/45.012; 372/46.01

(57) ABSTRACT

The performance characteristics of ridge waveguide QCL may be improved in accordance with the invention by replacing the insulating dielectric layers such as SiO₂, Si₃N₄ or SiC with p-type InP overgrowth layers as well as p-type AlInAs or InGaAsP overgrowth layers, for example.

### BACKGROUND

Conventional ridge waveguide quantum cascade lasers (QCL) typically have dielectric layers deposited around the ridge structure as shown in FIG. 1 to provide optical confinement and current blocking. Prior art QCL structure 100 has upper electrode 160 and lower electrode 110, n-type lower cladding layer 120, n-type upper cladding layer 140, QC active region 130, upper separate confinement heterostructure (SCH) layer 135, lower separate confinement heterostructure (SCH) layer 125, ridge region 145 and insulating dielectric layers 150 deposited around ridge region 145.

### SUMMARY OF THE INVENTION

The performance characteristics of ridge waveguide QCL may be improved in accordance with the invention by replacing the insulating dielectric layers such as SiO₂, Si₃N₄ or SiC with p-type InP overgrowth layers as well as p-type AlInAs or InGaAsP overgrowth layers, for example. The substitution of p-type non-insulating overgrowth layers for insulating dielectric layers around the ridge structure of a QCL improves lateral mode discrimination and allows high temperature operation by providing lower thermal resistance The doping, etch depth and waveguide width may be selected to provide modal discrimination such that the fundamental lateral mode experiences relatively small loss compared to the higher order modes. Hence, higher order modes are effectively filtered out.

### BRIEF DESCRIPTION OF THE DRAWINGS

FIG. 1 shows a prior art ridge waveguide quantum cascade laser.

FIG. 2 shows an embodiment of a quantum cascade laser in accordance with the invention.

FIG. 3 shows doping dependence of the real part of the refractive index and absorption loss in accordance with the invention.

FIG. 4 shows the computed refractive index versus thickness of the upper cladding layer in accordance with the invention.

FIG. 5 shows a structure in accordance with the invention for performing a one-dimensional slab waveguide simulation.

FIG. 6 shows the lateral optical confinement factor as a function of ridge width for various doping levels in accordance with the invention.

FIG. 7 shows mode loss calculations in accordance with the invention.

FIG. 8 compares fundamental lateral mode loss with first order mode loss in accordance with the invention.

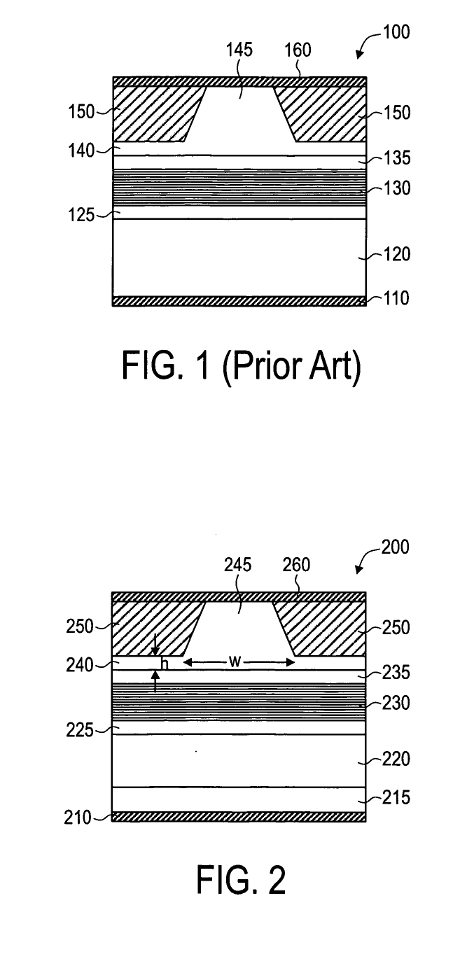

### DETAILED DESCRIPTION

In accordance with the invention, p-type overgrowth layers in ridge waveguide QCL comprised of, for example, InP:Zn or InP:Mg provide lower thermal resistance and better lateral mode selectivity in comparison to the use of dielectric layers. For AlGaAs-based QCLs, AlAs:C, AlAs:Zn or AlAs:Mg as well as AlGaAs:C, ALGaAs:Zn or AlGaAs:Mg p-type overgrowth layers may be used. For GaAsSb—InAs or GaAs based QCLs, GaSb:C, GaSb:Zn or GaSb:Mg p-type overgrowth layers may be used.

FIG. 2 shows QCL structure 200 in accordance with the invention. QCL structure 200 includes lower electrode 210 and upper electrode 260, n-doped substrate 215, n-type lower cladding layer 220, n-type upper cladding layer 240, QC active region 230, upper separate confinement heterostructure (SCH) layer 235, lower separate confinement heterostructure (SCH) layer 225, ridge region 245 and p-type overgrowth layers 250. Note that n-doped substrate 215 is typically more heavily doped than n-type lower cladding layer 220 which is typically grown over n-doped substrate 215. The presence of free holes in p-type overgrowth layers 250 contributes to free carrier absorption loss in the guided mode. However, the modal loss may be controlled by adjusting waveguide width w, etch depth h and the p-doping concentration in p-type overgrowth layers. Adjustment of the p-doping concentration, the waveguide width w and the etch depth h allows modal discrimination such that the fundamental lateral mode experiences relatively small loss compared to higher order modes. P-type doping concentrations in the range from about 10¹⁸ to about 10¹⁹ cm⁻³ are typically adequate to achieve the desired results in accordance with the invention.

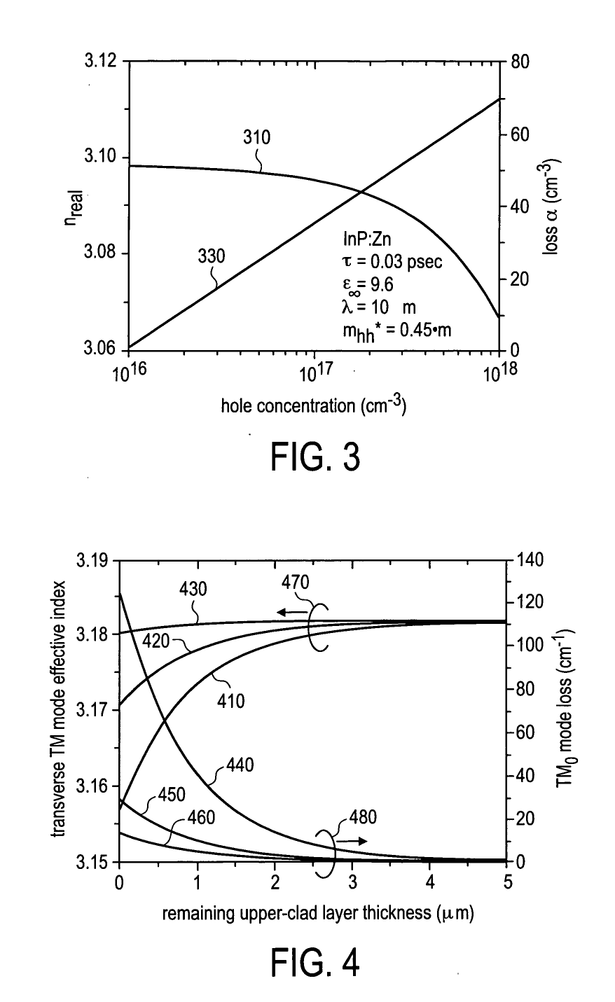

The modal loss associated with p-type overgrowth layers 250 may be quantified by using waveguide simulations which incorporate the Drude model for the dielectric function of doped semiconductors. For example, for the InP material system, curve 310 in FIG. 3 shows the doping dependence of the real part nᵣₑₐₗ of the refractive index and Curve 330 in FIG. 3 shows the doping dependence of the absorption loss a at a wavelength of about 10 μm for p-type overgrowth layers 250 with a scattering time of τ of about 0.03 psec. Even for moderate p-doping levels in the range of about 10¹⁷ cm⁻³, curve 330 shows the absorption loss a becomes relatively large. The absorption loss α actually increases more rapidly than is indicated by curve 330 because the scattering time τ decreases as the doping level increases. Including the dependence of scattering time τ on the doping level increases the absorption loss α for a doping level of about 10¹⁸ cm⁻³ from about 70 cm⁻¹ with a scattering time τ of about 0.03 psec as shown in FIG. 3 to about 86 cm⁻¹ with a scattering time τ of about 0.024 psec.

The effective index method is used to determine the lateral waveguiding of QCL structure 200 using the Drude model to establish the refractive index of p-type overgrowth layers 250 in FIG. 2. Table 1 shows the values for layers of QCL 200 in an embodiment in accordance with the invention for a wavelength of about 10 μm. Note p-InP overgrowth layer InP layer 250 and n-InP lower cladding layer 220 are taken to be semi-infinite for computational purposes. The thickness of n-type lower cladding layer 220 typically depends on the operational wavelength of QCL structure 200 and the substrate doping level. Typically, n-type lower cladding layer 220 must be grown sufficiently thick so that free-carrier loss from the more heavily n-doped substrate 215 is minimized which means that n-type lower cladding layer 220 must be thick enough to minimize the mode penetration into n-doped substrate 215. Typically, the required thickness is on the order of several microns but also depends on the particular wavelength and doping level of n-doped substrate 215. For the case of n-doped substrate 215 being heavily doped, in the range of 5×10¹⁸ cm⁻³, a typical thickness for n-type lower cladding layer 220 would be on the order of 2-3 μm for QCL structure 200 operating at about 5 μm and increased to a thickness on the order of 4-5 μm for QCL structure 200 operating at about 10 μm. For n-doped substrate 215 being lightly doped, in the range of 5×10¹⁷ cm⁻³, a typical thickness of n-type lower cladding layer 220 is typically on the order of 1 μm or less. Similar reasoning applies to the thickness of n-type upper cladding layer 240 where the loss is associated with upper electrode 260 which must be placed sufficiently far from the waveguide core which includes lower SCH layer 225, active region 230, and upper SCH layer 235. Hence, typical thicknesses for n-type upper cladding layer 240 and 245 are on the order of several microns and p-type overgrowth layer 250 is also several microns thick to planarize the top surface of QCL structure 200.

| | | doping level | |
|---|---|---|---|
| layer | layer thickness | (cm⁻³) | refractive index |
| p-InP overgrowth layer 250 | semi-infinite | 1 × 10¹⁸ | 3.07 + 0.00659i |
| | | 3 × 10¹⁸ | 3.00 + 0.02002i |
| | | 1 × 10¹⁹ | 2.87 + 0.1600i |
| n-InP upper cladding layer 240 | h | 1 × 10¹⁷ | 3.08 |
| n-InGaAs upper SCH layer 235 | 0.5 μm | 5 × 10¹⁶ | 3.37 |
| n-AlInAs/GaInAs active region 230 | 1.5 μm | 2 × 10¹⁶ | 3.28 |
| n-InGaAs lower SCH layer 225 | 0.5 μm | 5 × 10¹⁶ | 3.37 |
| n-InP lower cladding layer 220 | semi-infinite | 1 × 10¹⁷ | 3.08 |

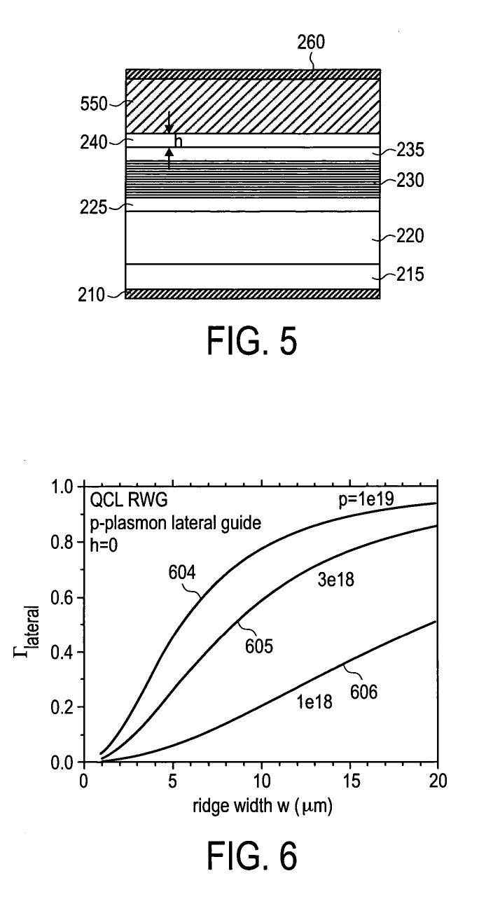

For computational purposes, the fundamental TM₀ transverse mode effective index is first evaluated using a one-dimensional slab waveguide simulation using the structure shown in FIG. 5 with p-InP overgrowth layer 550 displaced a distance h from upper SCH 235. FIG. 4 shows the computed refractive index values versus the thickness h of n-InP upper cladding layer 240 where imaginary component 480 of the transverse fundamental mode's complex refractive index corresponds to intensity loss. Real component 470 of the transverse fundamental mode's complex refractive index corresponds to the transverse effective index. Intensity loss values for imaginary component 480 are shown by curves 440, 450 and 460 which correspond to p-type doping levels of 1×10¹⁹ cm⁻³, 3×10¹⁸ cm⁻³ and 1×10¹⁸ cm⁻³, respectively. The transverse effective index values correspond to real component 470 and are shown by curves 410, 420 and 430 which correspond to p-type doping levels of 1×10¹⁹ cm⁻³, 3×10¹⁸ cm⁻³ and 1×10¹⁸ cm⁻³, respectively.

When the thickness h of n-InP upper cladding layer 240 is taken to be large in the context of the effective index method, FIG. 4 shows that the p-InP layers are far from the guided mode so that the mode loss extrapolates to zero (imaginary component 480 at h=5 μm) and the transverse effective index extrapolates to about 3.182 (real component 470 at h=5 μm). Taking h˜5 μm corresponds to evaluating the fundamental TM₀ transverse mode effective index in the plane bisecting ridge structure 245 in FIG. 2. As the thickness h of n-InP upper cladding layer 240 decreases the guided mode starts to overlap lossy p-InP overgrowth layer 550 which has a lower refractive index than n-InP upper cladding layer 240. Decreasing h corresponds to evaluating the fundamental TM₀ transverse mode effective index as one moves out laterally from the plane bisecting ridge structure 245 in FIG. 2. The effective index is reduced and the loss is increased. The loss and the refractive index difference between lossy p-InP overgrowth layer 550 and n-InP upper cladding layer 240 are the greatest for a p-type doping level of 1×10¹⁹ cm⁻³. For h˜0 μm, which corresponds physically to the case where p-InP overgrowth layer 250 is grown directly on upper SCH layer 235, the refractive index decreases by about 0.01 and the refractive index decreases by more than about 0.02 for p-doping levels of 3×10¹⁸ cm⁻³ and 1×10^{·}cm⁻⁶, respectively. This shows that QCL structure 200 forms a positive index guide where the refractive index difference between the middle of QCL structure 200 and the outer parts of QCL structure 200 may be relatively high.

FIG. 4 shows that the reduction of refractive index due to the high p-doping levels results in a positive refractive index step lateral waveguide. As the p-doping concentration is increased, the refractive index decreases yielding a better lateral waveguide. FIG. 6 shows lateral optical confinement factor Γₗₐₜₑᵣₐₗ as a function of ridge width w and h˜0 μm (see FIG. 2) for p-doping level curves 604 605 and 606 corresponding to 1×10¹⁹ cm⁻³, 3×10¹⁸ cm⁻³ and 1×10¹⁸ cm⁻³, respectively. Γₗₐₜₑᵣₐₗ is the highest for doping level curve 604 and Γₗₐₜₑᵣₐₗ is lowest for doping level curve 606. Γₗₐₜₑᵣₐₗ for doping level curve 606 is typically too low for applications and the required p-doping levels are typically on the order of about 3×10¹⁸ cm⁻³ or higher to create an acceptable waveguide for low threshold operation, typically about 2-3 kA/cm². For low threshold operation, the fundamental mode loss needs to be sufficiently low, typically less than about 10 to about 20 cm⁻¹ and the high lateral optical confinement factor, Γₗₐₜₑᵣₐₗ, needs to approach unity.

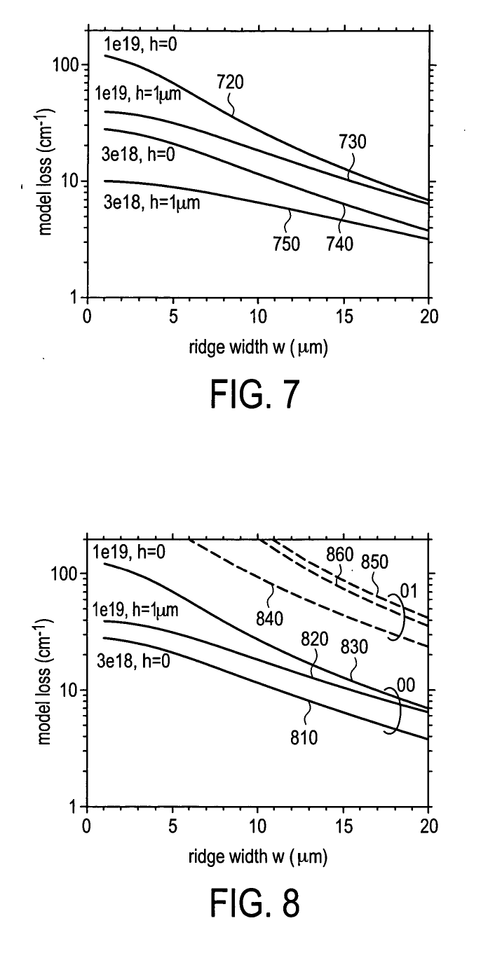

FIG. 7 shows mode-loss calculations in accordance with the invention. The ridge width w of the lateral fundamental mode loss is shown for four cases. Curve 720 shows the lateral fundamental mode loss for h˜0 μm at a p-doping level of 1×10¹⁹ cm⁻³ as a function of w. Curve 730 shows the lateral fundamental mode loss for h˜1 μm at a p-doping level of 1×10¹⁹ cm⁻³ as a function of w. Curve 740 shows the lateral fundamental mode loss for h˜0 μm at a p-doping level of 3×10¹⁸ cm⁻³ as a function of w. Curve 750 shows the lateral fundamental mode loss for h˜1 μM at a p-doping level of 3×10¹⁸ cm⁻³ as a function of w. The calculations presented in FIG. 8 show that the fundamental mode loss decreases as either the p-doping levels are reduced from 1×10¹⁹ cm⁻³ to 3×10¹⁸ cm⁻³ or h is increased which increases the distance between p-Inp overgrowth layers 250 which function as guiding layers and active region 230. With a suitable choice such as 1 μm for the thickness h of n-InP upper cladding layer 240 and more than 15 μm for ridge width w it is possible to achieve acceptable loss values α that are less than 10 cm⁻¹ even at p-doping levels as high as about 1×10¹⁹ cm⁻³.

Additionally, embodiments in accordance with the invention such as QCL structure 200 provide excellent mode discrimination. FIG. 8 compares fundamental lateral mode loss with first order lateral mode loss. Curve 810 represents the fundamental lateral mode loss as a function of ridge width w for h˜0 μm at a p-doping level of 3×10¹⁸ cm⁻³, curve 820 represents the fundamental lateral mode loss as a function of ridge width w for h˜1 μm at a p-doping level of 1×10¹⁹ cm⁻³ and curve 830 represents the fundamental lateral mode loss as a function of ridge width w for h˜0 μm at a p-doping level of 1×10¹⁹ cm⁻³; all at λ=10 μm. Curve 840 represents the first order lateral mode loss corresponding to the parameters of curve 810, curve 850 represents the first order lateral mode loss corresponding to the parameters of curve 820 and curve 860 represents the first order lateral mode loss corresponding to the parameters of curve 830. As can be seen from FIG. 8, the first order lateral mode loss represented by curve 840, curve 850 and curve 860 is many times greater than the fundamental lateral mode loss represented by curve 810, curve 820 and curve 830, respectively.

While the invention has been described in conjunction with specific embodiments, it is evident to those skilled in the art that many alternatives, modifications, and variations will be apparent in light of the foregoing description. Accordingly, the invention is intended to embrace all other such alternatives, modifications, and variations that fall within the spirit and scope of the appended claims.

1. A ridge waveguide quantum cascade laser structure comprising:
an upper cladding layer and a lower cladding layer with an active region between said cladding layers;
a ridge region formed in an upper portion of said upper cladding layer; and
a pair of doped overgrown non-insulating layers formed on both sides of said ridge regions and on those portions of the upper cladding layer extending sideward from a base of said ridge region.

2. The structure of claim 1 wherein said pair of doped non-insulating layers is doped with a p-dopant.

3. The structure of claim 2 wherein said p-dopant is selected from the group consisting of Zn and Mg.

4. The structure of claim 3 wherein a doping level is in the range from about 10¹⁸ cm⁻³ to about 10¹⁹ cm⁻³.

5. The structure of claim 1 having an operating wavelength of about 10 μm.

6. The structure of claim 1 wherein said pair of doped non-insulating layers comprise InP.

7. The structure of claim 1 wherein said pair of doped non-insulating layers comprise AlGaAs.

8. The structure of claim 1 wherein said pair of doped non-insulating layers comprise GaSb.

9. The structure of claim 1 further comprising a separate confinement heterostructure layer disposed between said active region and said upper cladding layer.

10. The structure of claim 1 wherein said base of said ridge region has a width greater than about 15 μm.

11. A method for a ridge waveguide quantum cascade laser structure comprising:
providing an upper cladding layer and a lower cladding layer and placing an active region between said cladding layers;
forming a ridge region in an upper portion of said upper cladding layer; and
forming a pair of doped overgrown non-insulating layers on both sides of said ridge regions and on those portions of the upper cladding layer extending sideward from a base of said ridge region.

12. The method of claim 11 wherein said pair of doped non-insulating layers is doped with a p-dopant.

13. The method of claim 12 wherein said p-dopant is selected from the group consisting of Zn and Mg.

14. The method of claim 13 wherein a doping level is in the range from about 10¹⁸ cm⁻³ to about 10¹⁹ cm⁻³.

15. The method of claim 11 having an operating wavelength of about 10 μm.

16. The method of claim 11 wherein said pair of doped non-insulating layers comprise InP.

17. The method of claim 11 wherein said pair of doped non-insulating layers comprise AlGaAs.

18. The method of claim 11 wherein said pair of doped non-insulating layers comprise GaSb.

19. The method of claim 11 further comprising a separate confinement heterostructure layer disposed between said active region and said upper cladding layer.

20. The method of claim 11 wherein said base of said ridge region has a width greater than about 15 μm.
